(19) United States
(12) Patent Application Publication
(10) Pub. No.: US 2010/0163737 A1
(43) Pub. Date: Jul. 1, 2010

(54) RADIATION DETECTOR, METHOD OF MANUFACTURING RADIATION DETECTOR, AND METHOD OF MANUFACTURING SUPPORTING SUBSTRATE

(76) Inventors: Satoshi Masuda, Neyagawa-shi (JP); Tomoo Izumi, Toyonaka-shi (JP)

Correspondence Address: SIDLEY AUSTIN LLP, 717 NORTH HARWOOD, SUITE 3400, DALLAS, TX, 75201, US

(21) Appl. No.: 12/600,668

(22) PCT Filed: May 14, 2008
(86) PCT No.: PCT/JP2008/058834

§ 371 Date: Nov. 18, 2009

(30) Foreign Application Priority Data
May 24, 2007 (JP) 2007-137602

(51) Int. Cl. G01T 1/20; H01L 51/48; H01L 31/0232

(52) U.S. Cl. 250/366; 250/361 R; 438/82; 438/69; 257/E51.012; 257/E31.129

(57) ABSTRACT

Disclosed is a radiation detector characterized by comprising a scintillator layer formed on one side of a supporting substrate and composed of a phosphor converting radiation into visible light, a plurality of transparent electrodes formed in a matrix on the other side of the supporting substrate, a photoelectric conversion layer formed on the transparent electrodes and containing an organic semiconductor material, and an upper electrode formed on the organic semiconductor layer. This radiation detector is further characterized in that collector elements for focusing visible light emitted from the scintillator layer irradiated with radiation on the organic semiconductor layer are embedded in a matrix in the supporting substrate at positions facing the transparent electrodes.

### TECHNICAL FIELD

The present invention relates to a radiation detector, a method of manufacturing the radiation detector, and a method of manufacturing a supporting substrate.

### BACKGROUND

Radiation images obtained by detecting an intensity distribution passing through an object by exposing the object to radiation such as X-rays have been widely utilized in medial diagnosis so far. In recent years, developed has been a radiation image capturing system equipped with a radiation detector as a radiation image detecting apparatus to detect radiation during shooting to convert it into an electrical signal so as to be detected as radiation image information.

The radiation detector, for example, possesses a scintillator by which radiation is converted into visible light, and a substrate on which placed in a matrix state is a photoelectric conversion element to convert into an image signal for a radiation image as a whole by detecting visual light producing luminescence from each portion of the scintillator, are laminated (refer to Patent Documents 1 and 2, for example).

Such the radiation detector is designed in such a way that a photoelectric conversion element such as a photodiode or the like is driven with a thin film transistor (TFT). A method of preparing a photodiode and a TFT on the same substrate by using a silicon system inorganic material such as a-Si or poly-Si is disclosed in Patent Documents 1 and 2, for example. However, in the case of a process of manufacturing such the inorganic semiconductor, not only expensive facilities but also complicated processes are necessary to conduct a vacuum process and a high temperature process.

On the other hand, in the case of a process of manufacturing a semiconductor element employing an organic material, production cost can be suppressed since a process exhibiting excellent productivity such as printing or coating is usable in place of the vacuum process and the high temperature process. The selection range of organic materials is larger than that of inorganic materials. Because of these factors, research and development of a TFT technique (organic TFT) employing an organic semiconductor material has been actively done in recent years (refer to Patent Document 3, for example).

However, in cases where a photoelectric conversion element is prepared by utilizing an organic material, a transparent electrode is desired to be formed, but there appears a problem such that properties of an organic semiconductor layer are degraded via influence of heat, plasma or the like applied during formation of the transparent electrode when forming the transparent electrode on the organic semiconductor layer. For this reason, proposed is a photoelectric conversion element structured in such a way that the photoelectric conversion layer is exposed to light via the transparent substrate from the back surface of the substrate by layering a photoelectric conversion layer composed of the organic semiconductor layer and the upper electrode made of aluminum as a material in order on the transparent electrode having been film-formed on a transparent substrate (refer to Non-patent Document 1, for example).

Patent Document 1: Japanese Patent No. 3066944

Patent Document 2: Japanese Patent No. 3494683

Patent Document 3: Japanese Patent o.P.I. Publication No. 10-190001

Non-patent Document 1: The Society of Photographic Science and Technology of Japan, vol. 69, No. 5, pages 327-331 (2006)

### DISCLOSURE OF THE INVENTION

### Problems to be Solved by the Invention

In the case of a radiation detector disclosed in Patent Documents 1 and 2, a scintillator is layered on a transparent electrode provided on an upper layer of a photoelectric conversion layer made of an inorganic material. However, in the case of a light radiation detector fitted with an organic semiconductor layer, a scintillator can not be layered on the upper layer of the photoelectric conversion layer, since a transparent electrode or the like by which properties of the photoelectric conversion layer tend to be degraded is desired to be formed before forming the photoelectric conversion layer composed of an organic semiconductor layer as described in Non-patent Document 1. For this reason, the inventors have studied a method of forming a scintillator on a substrate surface on the opposite side of another substrate surface on which a photoelectric conversion element is formed in such a way that the photoelectric conversion layer is exposed to light via the transparent substrate from the back surface of the substrate.

However, when forming a scintillator on a substrate surface on the opposite side of another substrate surface on which a photoelectric conversion element, light emitted via wavelength-conversion of radiation with the scintillator is scattered into a wide range during passing through the substrate because of scattered light. Therefore, there was a problem such that image-taken images appeared blurred, and scattered light entering TFT produced malfunction.

The present invention has been made on the basis of the above-described problems, and it is an object of the present invention to provide a radiation detector including an organic semiconductor material, by which a clear image exhibiting excellent sensitivity can be image-taken, as well as a method of manufacturing a radiation detector and a method of manufacturing a supporting substrate.

### Means to Solve the Problems

The object of the present invention can be accomplished by the following structures.

(Structure 1) A radiation detector comprising a scintillator layer comprising a phosphor to convert radiation into visible light, formed on one surface of a supporting substrate; a transparent electrode formed on another surface of the supporting substrate; a photoelectric conversion layer comprising an organic semiconductor material, formed on the transparent electrode; and an upper electrode formed on the photoelectric conversion layer, wherein light collectors to collect the visible light emitted by exposing the scintillator layer to radiation into the photoelectric conversion layer are embedded in the form of a matrix at a position facing the transparent electrode in the supporting substrate.

(Structure 2) The radiation detector of Structure 1, comprising the supporting substrate not transmitting the visible light.

(Structure 3) The radiation detector of Structure 1 or 2, comprising each of a plurality of the transparent electrodes formed in the form of a matrix, on the another surface of the supporting substrate.

(Structure 4) A method of manufacturing a supporting substrate employed for the radiation detector of any one of Structures 1-3, comprising the steps of forming a plurality of through-holes in the form of a matrix so as to pass through from one surface of the supporting substrate to another surface of the supporting substrate, and filling a transparent material in the through-holes.

(Structure 5) The method of Structure 4, wherein the step of forming a plurality of through-holes in the form of a matrix is a step of forming the through-holes employing a nanoimprint technique.

(Structure 6) A method of manufacturing a radiation detector, comprising the steps of forming a scintillator layer comprising a phosphor to convert radiation into visible light, on one surface of the supporting substrate manufactured by the method of Structure 4 or 5; forming a transparent electrode on another surface of the supporting substrate; forming a photoelectric conversion layer comprising an organic semiconductor material, on the transparent electrode; and forming an upper electrode on the photoelectric conversion layer, wherein the photoelectric conversion layer is formed with a solution in which an electron-accepting organic material and an electron-releasing organic material are dissolved in an organic solvent.

(Structure 7) A radiation detector comprising a scintillator layer comprising a phosphor to convert radiation into visible light, formed on one surface of a supporting substrate; a protective film formed on the scintillator layer; a transparent electrode formed on the protective film; a photoelectric conversion layer comprising an organic semiconductor material, formed on the transparent electrode; and an upper electrode formed on the photoelectric conversion layer.

(Structure 8) The radiation detector of Structure 7, wherein the transparent electrode has a thickness T1 of at least 10 nm and not more than 500 nm.

(Structure 9) The radiation detector of Structure 7 or 8, wherein an overall reflectance produced at an interface between the scintillator layer and the photoelectric conversion layer is within 110% of a theoretical minimum value of the reflectance with respect to a central wavelength of light emitted by the scintillator layer.

(Structure 10) The radiation detector of any one of Structures 7-9, comprising a plurality of the transparent electrodes formed in the form of a matrix on the protective film.

(Structure 11) A method of manufacturing the radiation detector of any one of Structures 7-10, comprising the step of forming the photoelectric conversion layer, employing a solution in which an electron-accepting organic material and an electron-releasing organic material are dissolved.

### EFFECT OF THE INVENTION

In the present invention, a radiation detector including an organic semiconductor material, by which a clear image exhibiting excellent sensitivity can be image-taken, as well as a method of manufacturing a radiation detector and a method of manufacturing a supporting substrate can be provided since light emitted via wavelength-conversion of radiation with a scintillator can be effectively collected into a photoelectric conversion element.

### BRIEF DESCRIPTION OF THE DRAWINGS

FIGS. 1a-1e each are a schematic cross-sectional view of a supporting substrate to explain a manufacturing process of image sensor 20 in the first embodiment.

FIGS. 2a and 2b each are a circuit diagram schematically showing radiation detector 22 of the present invention.

FIGS. 3a and 3b each are an illustration diagram to explain a process of forming through-hole 50 in supporting substrate 1.

FIGS. 4a, 4b and 4c each are a schematic cross-sectional view of a supporting substrate to explain a manufacturing process of image sensor 20 in the second embodiment.

### EXPLANATION OF NUMERALS

1 Supporting substrate
2 Gate electrode
5 Active layer
7 Gate insulation layer
8 Source
9 Drain
20 Image sensor
22 Radiation detector
50 Through-hole
51 Light collector
100 Transparent electrode
101 Photoelectric conversion layer
102 Upper electrode
103 Protective film
112 Passivation layer
131 Scintillator
133 Protective film

### DESCRIPTION OF THE PREFERRED EMBODIMENTS

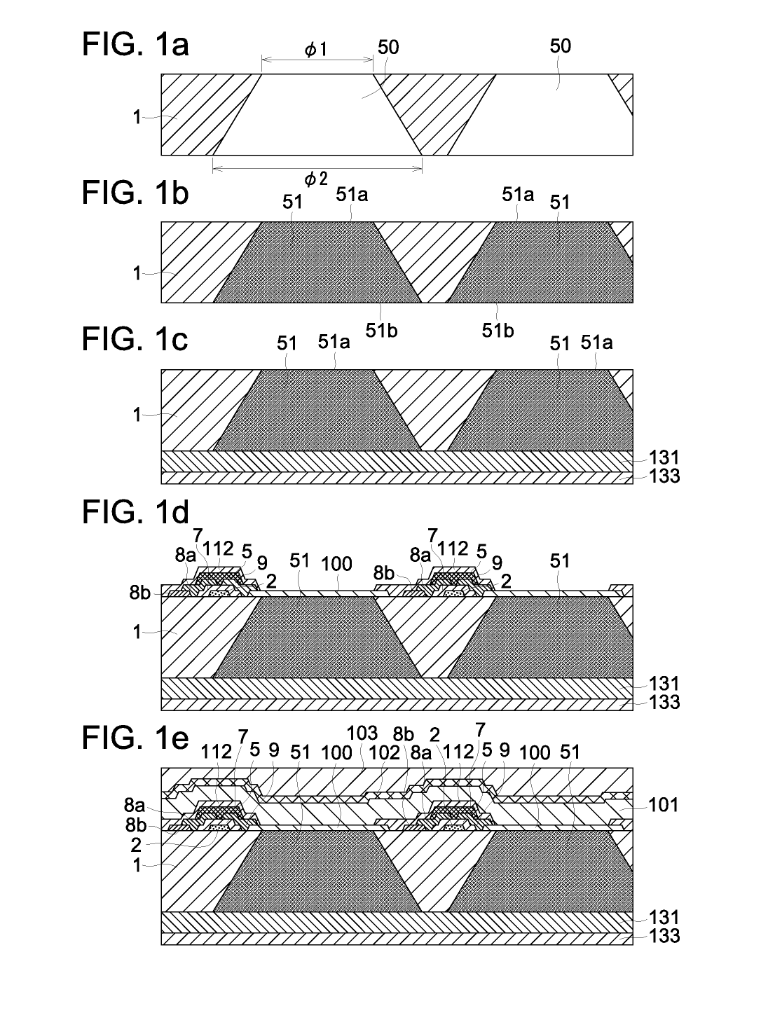

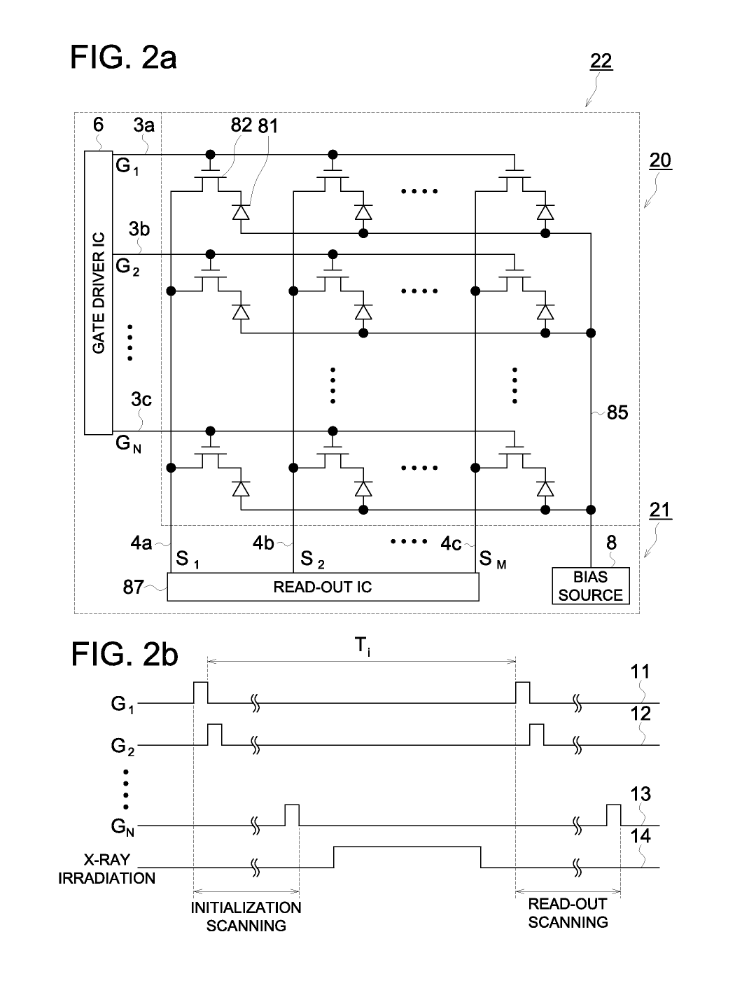

Next, the first embodiment in the present invention will be described in detail referring to FIGS. 1a-1e and FIGS. 2a-2b.

In the first embodiment, described will be a radiation detector possessing an image sensor in which a scintillator is formed on one surface of a supporting substrate exhibiting an insulation property, and a readout thin film transistor (hereinafter, a thin film transistor is called TFT) and a bulk-heterojunction type photoelectric conversion element are formed two-dimensionally in the form of a matrix on the facing surface.

FIGS. 1a-1e each are a schematic cross-sectional view of a supporting substrate to explain a manufacturing process of image sensor 20 in the first embodiment, and FIGS. 2a and 2b each are a circuit diagram schematically showing radiation detector 22 of the present invention.

FIG. 2a is a circuit diagram schematically showing radiation detector 22 equipped with image sensor 20 in which a plurality of pixels each composed of photoelectric conversion element 81 and readout TFT 82 are placed in the form of a matrix, and drive circuit section 21 to read charge produced by photoelectric conversion element 81 through readout TFT 82 as a voltage. Further, FIGS. 1a-1e each are a diagram schematically showing each of cross-sections of two pixels composed of readout TFT 82 and photoelectric conversion element 81 provided on supporting substrate 1 as to each step of manufacturing image sensor 20 shown in FIG. 2a. FIG. 1e shows a cross-section of two pixels in the situation where image sensor 20 is completed.

That is, shown are two photoelectric conversion elements 81 composed of transparent electrode 100, photoelectric conversion layer 101 and upper electrode 102, and two TFTs 82 composed of source electrode 8, drain electrode 9, gate electrode 2, gate insulation layer 7 and active layer 5. In FIGS. 1a-1e, numeral 1 represents an opaque insulation supporting substrate, numeral 112 represents a passivation layer (planarization layer) made of SiN, SiO₂, BCB (Benzo Cyclo Butene), PI (Plyimide) or the like, numeral 102 represents an upper electrode, and numeral 101 represents a photoelectric conversion layer containing an organic semiconductor material. In addition, numeral 100 represents a transparent electrode containing a transparent conductive material such as ITO, SnO₂ or the like.

Upper electrode 102 on photoelectric conversion element 81 is a common electrode to apply a bias from bias line 85 to all of photoelectric conversion elements 81 constituting image sensor 20. In the present embodiment, an example in which a plurality of transparent electrodes 100 formed in the form of a matrix each are connected to drain electrode 9 for readout TFT 82 will be further described.

The manufacturing steps of image sensor 20 in the first embodiment will be sequentially described referring to FIGS. 1a-1e, FIGS. 2a-1b and FIGS. 3a-3b.

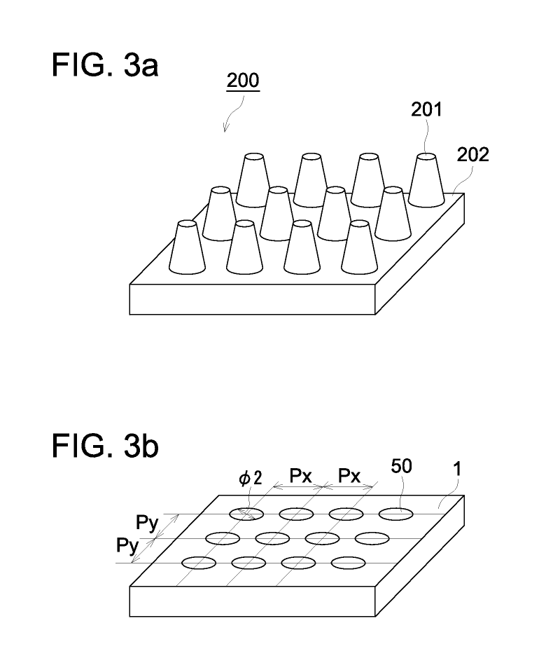

FIGS. 1a-1e each show a cross-sectional view of a section formed from two pixels of supporting substrate 1. FIGS. 3a-3b each are an illustration diagram to explain a process of forming through-hole 50 in supporting substrate 1.

In the first embodiment concerning the method of manufacturing image sensor 20 of the present invention, the following steps of S1 to S12 will be described.

S1: Step of forming light collector 51 in supporting substrate 1

S1-1: Step of forming through-hole 50

S1-2: Step of filling a transparent material in through-hole 50 of supporting substrate 1

S2: Step of forming scintillator 131

S3: Step of forming protective film 133

S4: Step of forming transparent electrode 100

S5: Step of forming gate electrode 2 and source line 8b

S6: Step of forming gate insulation layer 7

S7: Step of forming source electrode 8a and drain electrode 9

S8: Step of forming active layer 5

S9: Step of forming passivation layer 112

S10: Step of forming photoelectric conversion layer 101

S1: Step of forming upper electrode 102

S12: Step of forming protective layer 103

Next, each of the steps will be sequentially described.

S1: Step of Forming Light Collector 51 in Supporting

As shown in FIG. 1b, light collector 51 is formed on supporting substrate 1. In the present invention, supporting substrate 1 is not specifically limited to material. Low melting temperature glass and a film substrate formed of PEN, PES, PC, TAC or the like are usable, for example, but a transparent material such as glass or the like is desired to be colored so as neither to pass through light, nor to enter undesired light into TFT or the like which will be formed later on. When a cross-section of light collector 51 is designed to be conical in shape in such away that diameter φ1 of outgoing light surface 51a is smaller than diameter φ2 of incoming light surface 51b, light produced by luminescence of scintillator 131 can be effectively collected into photoelectric conversion layer 100 which will be prepared later on.

Material contained in light collector 51 is not specifically limited, as long as the material is a transparent material, but an acrylic resin, a urethane resin, an epoxy resin, a polyimide resin and so forth are preferable. As the resin, a thermoplastic resin, a thermosetting resin and a UV curable resin are provided, but any of them is usable. When material of supporting substrate 1 is a transparent material, material exhibiting higher refractive index than that of the material of supporting substrate 1 is preferably employed. For example, when the material of supporting substrate 1 is a transparent low melting temperature glass, polyimide exhibiting higher refractive index than that of the material of supporting substrate 1, for example, may be used. Scattering light entering from incoming light surface 51b is reflected at the interface between light collector 51 and supporting substrate 1, and collected to outgoing light surface 51a.

The step of forming light collector 51 will be described in detail.

S1-1: Step of Forming Through-Hole 50

As shown in FIG. 1a, through-hole 50 showing a cross-section of trapezoidal shape is formed. FIG. 3a is an appearance diagram showing shape of a part of die 200 employed for forming through-hole 50, and FIG. 3b is an appearance diagram showing a part of supporting substrate 1 in which through-hole 50 has been formed. Symbol φ1 represents a hole diameter on outgoing light surface 51a of supporting substrate 1 for through-hole 50, and Symbol φ2 represents a hole diameter on incoming light surface 51b. Further, Px and Py represent distance intervals of through-holes 50 placed on supporting substrate 1 in the form of a matrix. For example, supporting substrate 1 has a thickness of roughly 0.2-1 mm, φ1 is 100-200 nm, φ2 is 200-400 nm, and each of Px and Py is roughly 300-500 nm.

Such the through-holes 50 can be prepared employing a nanoimprint technique. As the nanoimprint technique, there are techniques such as a heat type nanoimprint technique, a UV type nanoimprint technique and so forth, but described is an example of forming through-hole 50 via a heat type nanoimprint process by using a low melting temperature glass such as PYREX (registered trademark) for supporting substrate 1, for example.

S1-1-1: Heating Step

Die 200 and supporting substrate 1 are first heated to a temperature higher than the glass transition temperature of the low melting temperature glass as material of supporting substrate 1. Since the glass transition temperature is higher than 300° C., material exhibiting excellent high temperature resistance and excellent surface lubricity, such as glass carbon, for example, may be employed.

S1-1-2: Step of Pressing

Die pattern 201 of die 200 is pressed onto supporting substrate 1 while heating to transfer die pattern 201 onto supporting substrate 1. When material of supporting substrate 1 is PYREX (registered trademark), die 200 is pressed at 5 Pa for about 20 minutes after heating to 650° C. The top of die pattern 201 has a diameter of φ1, and a diameter around base plate 202 is φ2.

S1-1-3: Step of Cooling/Releasing

Die 200 and supporting substrate 1 are cooled to temperature lower than glass transition temperature of supporting substrate 1 to release die 200 from supporting substrate 1. Through-holes 50 are formed by releasing die 200 as shown in FIG. 3b. A diameter of through-hole 50 on the surface of supporting substrate 1 shown in FIG. 3b is φ2, and another diameter of through-hole 50 on the surface on the other side is φ1.

S1-2: Step of Filling a Transparent Material in Through-Hole 50 of Supporting Substrate 1.

A transparent material, for example, is dropped in through-hole 50. As the resin material, a thermoplastic resin, a thermosetting resin, a UV curable resin and so forth are usable. When employing the thermoplastic resin, for example, it is dropped in through-hole 50 from the side shown in FIG. 3b while heating the thermoplastic resin, and filled in through-hole 50, followed by cooling. The resin after cooling collects light entering from incoming light surface 51b into outgoing light surface 51a as a plurality of light collectors 51 embedded in supporting substrate 1 as shown in FIG. 1b.

In addition, when the dropped thermoplastic resin is designed to be raised higher than the surface of supporting substrate 1 because of surface tension, the light collection effect can be further produced via a lens effect.

S2: Step of Forming Scintillator 131

Scintillator 131 is formed on the incoming light surface 51b side of supporting substrate 1 in which light collector 51 is embedded, employing an evaporation method, for example. Scintillator 131 containing a phosphor as a principal component produces fluorescence having a wavelength of 300-800 nm via incident radiation.

As material of scintillator 131, usable is phosphors disclosed in Japanese Patent o.P.I. Publication No. 2006-73856. Specifically, cesium iodide (CsI:X, X representing an activator) and gadolinium oxysulfide (Gd₂O₂S:X, X representing an activator) are preferable in view of high X-ray absorption as well as high emission efficiency. By employing these, a high quality image with low noise can be obtained.

Further, scintillator 131 preferably has a columnar crystal structure. That is, in the case of presence of the columnar crystals, since an optical guide effect is obtained in such a way that the columnar crystals prevent light emission within the crystals from radiating outside from side surfaces of the crystals, degradation of sharpness is possible to be inhibited, and X-ray absorption is increased by thickening the phosphor layer thickness to improve graininess.

S3: Step of Forming Protective Film 133

Protective film 133 is formed in such a way that the upper surface of scintillator 131 and side surfaces of scintillator 131 are covered. Protective film 133 is formed with polyimide, for example, as a material, employing a spin-coating method.

S4: Step of Forming Transparent Electrode 100

Transparent electrode 100 is formed on the outgoing light surface 51a side of supporting substrate 1 in which light collector 51 is embedded, employing a sputtering method, for example.

Transparent electrode 100 means an electrode transmitting light to be photoelectrically converted, and light having a wavelength of 300-800 nm. As the material, for example, transparent conductive metal oxide such as indium tin oxide (ITO), SnO₂, ZnO₂ or the like, a metal thin film made of gold, silver, platinum or the like, and a conductive polymer are preferably employed, but the present invention is not limited thereto.

Thickness t1 of transparent electrode 100 is preferably 500 nm or less in such a way that at least 700 of emission light of scintillator 131 is transmitted. On the other hand, a thickness of at least 10 nm is desired to obtain conductivity of transparent electrode 100. Accordingly, thickness t1 of transparent electrode 100 preferably satisfies 10 nm≦t1≦500 nm.

S5: Step of Forming Gate Electrode 2 and Source Line 8b

Gate electrode 2 and source line 8b are formed on the outgoing light surface 51a side of supporting substrate 1 in which light collector 51 is embedded. Various metal thin films are usable for gate electrode 2 and source line 8b. For example, usable are a low resistance metal material such as Al, Cr, Au, Ag or the like and a multilayered structure formed from the foregoing metal, and those obtained by doping another material in order to improve heat resistance of a metal thin film and adhesion to a supporting substrate, and to reduce defects. A transparent electrode formed of ITO, IZO, SnO, ZnO or the like is also usable. As a manufacturing method thereof, a musk evaporation method by which patterning can be made in intended shape, a photolithography method, and various printing methods are utilized.

S6: Step of Forming Gate Insulation Layer 7

Gate insulation layer 7 is formed, as shown in FIG. 1d.

Gate insulation layer 7 is formed via a spin-coating method, for example. As gate insulation layer 7, an acrylic resin, a urethane based resin, an epoxy based resin, a polyimide based resin and so forth are preferable in order to obtain specifically flexibility. As a resin, there are a thermoplastic resin and a thermosetting resin, but any of them is usable. On the other hand, an insulating film or the like as an inorganic film is not suitable in view of poor flexibility and unworkability.

S7: Step of Forming Source Electrode 8a and Drain Electrode 9

Source electrode 8a and drain electrode 9 are formed on gate insulation layer 7. As to source electrode 8a and drain electrode 9, film formation is made via sputtering of gold. In addition, gold is exemplified herein, but the material is not specifically limited to gold, and the material such as platinum, silver, copper, aluminum or the like is usable. Or, usable are a conductive organic material typified by PEDOT/PSS as a coating material and another coating material in which metal nanoparticles are dispersed.

S8: Step of Forming Active Layer 5

Material of active layer 5 is not limited to an organic semiconductor material, but the organic semiconductor material is preferable since the layer can be formed via printing, coating or the like. In the case of the organic semiconductor material, it has no restriction on material thereof. The organic polymeric material as well as a low molecular material such as pentacene or the like is usable.

As an example of coatable material, usable is any of soluble semiconductor materials such as polythiophenes such as poly(3-hexylthiophene) and so forth, aromatic oligomers such as oligothiophene having a side chain on the basis of a hexamer of thiophene, pentacenes exhibiting high solubility in which a substituent is contained in pentacene, a copolymer (F8T2) obtained from fluorene and bi-thiophene, polythienylenevinylene, phthalocyanine and so forth.

In the foregoing steps of S5-S8, TFT 82 composed of gate electrode 2, gate insulation layer 7, source electrode 8a, drain electrode 9, and active layer 5 was possible to be prepared.

S9: Step of Forming Passivation Layer 112

Passivation layer 112 is formed by coating polyimide, for example, employing a spin-coating method.

S10: Step of Forming Photoelectric Conversion Layer 101

For example, a solution in which an electron-accepting organic material and an electron-releasing organic material are dissolved in an organic solvent is coated on the entire surface of supporting substrate 1 having been subjected to completing the steps up to S9, employing a spin-coating method, followed by drying to form bulk-heterojunction type photoelectric conversion layer 101. A chlorobenzene solution having a weight ratio of PCBM (butyric acid methylester) as an electron-accepting organic material to P3HT (poly-3-hexylthiophene) as an electron-releasing organic material in 7:3 is coated via spin-coating, followed by heating with an oven at 100° C. for 30 minutes to form 70 nm thick photoelectric conversion layer 101.

In this way, bulk-heterojunction type photoelectric conversion layer 101 can be composed of only one layer as a photoelectric conversion layer, whereby the step can be simplified.

The electron-accepting organic material and the electron-releasing organic material are not limited thereto, and usable are various materials disclosed in Japanese Patent o.P.I. Publication No. 2005-32793, for example. Further, application to the present invention is not limited to the bulk-heterojunction type photoelectric conversion layer, and formed may be a stacking type photoelectric conversion layer in which layers formed of an electron-releasing organic material and layers formed of an electron-releasing organic material, disclosed in Japanese Patent o.P.I. Publication No. 2005-32793, for example, are laminated.

S11: Step of Forming Upper Electrode 102

Upper electrode 102 is formed on photoelectric conversion layer 101. Upper electrode 102 is formed via evaporation of a metal material such as Al, Ag, Au, Pt or the like, for example.

A photoelectric conversion element composed of transparent electrode 100, photoelectric conversion layer 101 and upper electrode 102 was able to be prepared via the foregoing steps.

S12: Step of Forming Protective Layer 103

Polyimide, for example, is coated onto the upper layer of upper electrode 102 by a spin-coating method.

This is the end of the manufacturing process of image sensor 20.

Since in such the way, light emitted by scintillator 131 is collected into photoelectric conversion layer 101 with light collector 51 embedded in supporting substrate 1, clear images exhibiting excellent sensitivity can be image-taken with neither image-blurring of image-taken images, nor malfunction caused by scattering light entering TFT.

Next, radiation detector 22 equipped with image sensor 20 will be described, referring to FIGS. 2a-2b.

In FIG. 2a, numeral 81 represents a photoelectric conversion element, and numeral 82 represents a reading TFT. The source of reading TFT 82 is connected to source buses 4a, 4b, . . . 4c; the drain is connected to a cathode of photoelectric conversion element 81; and the gate is connected to gate buses 3a, 3b, . . . 3c. An anode of photoelectric conversion element 81 is connected to bias line 85, and bias line 85 is connected to bias source 8 to apply a negative bias voltage. Gate buses 3a, 3b, . . . 3c are connected to output terminals of gate driver IC 6 G1, G2, . . . G_{N}, respectively, and source buses 4a, 4b, . . . 4c are connected to output terminals of read-out IC 87 S1, S2, . . . S_{M}. Image sensor 20 forms one pixel obtained via combination of one photoelectric conversion element 81 and one reading TFT 82, and possesses pixels of N rows×M columns.

Gate driver IC 6 possesses gate buses 3a, 3b, . . . 3c connected to output terminals thereof G1, G2, . . . G_{N}, and a positive voltage is output in order to scan gate buses 3a, 3b, . . . 3c. Read-out IC 87 possesses source buses 4a, 4b, . . . 4c connected to output terminals thereof S1, S2, . . . S_{M}, and a positive voltage is output. Each of output terminals of read-out IC 87 S1, S2, . . . S_{M} is equipped with a charge-voltage conversion circuit, and serves as a function in which the charge amount running out to source buses 4a, 4b, . . . 4c is converted into voltage.

Operation of radiation detector 22 will be described referring to a circuit diagram shown in FIG. 2a and a timing chart shown in FIG. 2b. Numerals 11, 12 and 13 each represent voltage of output terminals G1, G2, . . . G_{N}. When gate buses 3a, 3b, . . . 3c become high, TFT 82 connected to a gate line thereof becomes an on-state. In this case, since positive voltage is output from output terminals S1, S2, . . . S_{M} of read-out IC 87 to source buses 4a, 4b, . . . 4c, photoelectric conversion element 81 connected to TFT 82 in an on-state is inversely biased, and charge is charged up in capacity of photoelectric conversion element 81. Charging current running into photoelectric conversion element 81, that is, charge running into source buses 4a, 4b, . . . 4c from output terminals S1, S2, . . . S_{M} of read-out IC 87 is converted with read-out IC 87 via charge-voltage conversion, and read out as voltage. When gate buses 3a, 3b, . . . 3c become low, TFT 82 connected to a gate line thereof becomes an off-state, and stored charge of photoelectric conversion element 81 connected to TFT 82 is retained.

A duration indicated as initialization scanning in FIG. 2b is a scanning duration to charge all the photoelectric conversion elements 81 for preparation of taking a radiation image. Numeral 14 in FIG. 2b represents radiation irradiation, a duration in the high state indicates a radiation-irradiating duration. Radiation irradiation is conducted after completing initialization scanning of radiation detector 22. Upon radiation irradiation, scintillator 131 exposed to radiation produces fluorescence, and electron-hole pairs are generated in photoelectric conversion element 81 by which this fluorescence has been received to discharge stored charge. For this reason, charge stored in photoelectric conversion element 81 is reduced by an amount equivalent to electron-hole pairs generated depending on the amount of light received.

Following radiation irradiation, read-out scanning shown in FIG. 2b is conducted. Voltage converted via charge-voltage conversion, which is read out from read-out IC 87 during read-out scanning corresponds to charge annihilated via discharge from photoelectric conversion element 81 during radiation irradiation. Accordingly, an image obtained via radiation entering a phosphor layer can be two-dimensionally read out as voltage.

Symbol Ti in FIG. 2b represents an integral duration, and in this duration, electron-hole pairs caused by visible light generated from scintillator 131 are integrated by photoelectric conversion element 81. Accordingly, integral duration Ti is preferably designed so as to include an irradiation duration of radiation and a light emission duration of a phosphor layer.

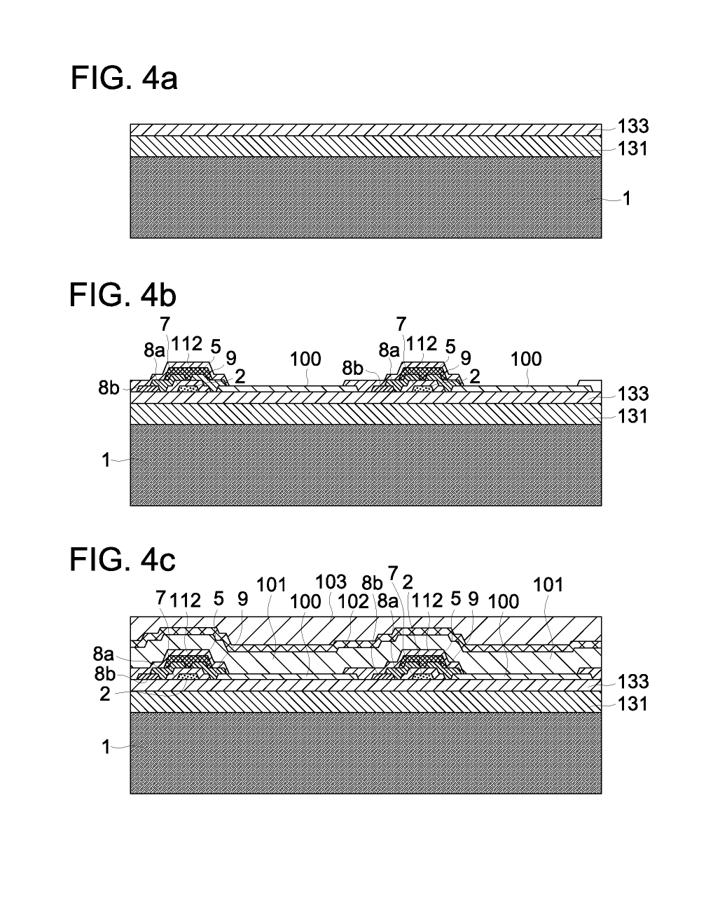

Next, manufacturing steps of image sensor 20 in the second embodiments will be described in order, referring to FIG. 4. Incidentally, the same numbers are given with respect to the same steps as in the first embodiment, and explanation thereof is omitted.

FIGS. 4a-4c each are a cross-sectional view showing a section to form 2 pixels on supporting substrate 1. Unlike the first embodiment, an organic TFT and a photoelectric conversion element are formed on scintillator 131, and step S1 of forming light collector 51 in supporting substrate 1 is omitted.

As the second embodiment for a method of manufacturing image sensor 20 of the present invention, the following steps S2-S12 will be described.

S2: Step of forming scintillator 131

S3: Step of forming protective film 133

S4: Step of forming transparent electrode 100

S5: Step of forming gate electrode 2 and source line 8b

S6: Step of forming gate insulation layer 7

S7: Step of forming source electrode 8a and drain electrode 9

S8: Step of forming active layer 5

S9: Step of forming passivation layer 112

S10: Step of forming photoelectric conversion layer 101

S11: Step of forming upper electrode 102

S12: Step of forming protective layer 103

The supporting substrate employed in the second embodiment is not specifically limited as long as it is a radiation-transmitting material. For example, a low melting temperature glass and a film substrate such as PEN, PES, PC, TAC or the like are usable, but a transparent material such as glass or the like is desired to be colored so as neither to pass through light, nor to enter undesired light into TFT or the like which will be formed later on.

Next, the steps each will be described in order.

S2: Step of Forming Scintillator 131

As shown in FIG. 4a, scintillator 131 is formed on the surface of supporting substrate 1 by an evaporation method employing CsI, for example, as a material. Similarly to the first embodiment, another material is usable for scintillator 131.

S3: Step of Forming Protective Film 133

Protective layer 133 is formed in such a way that the upper layer of scintillator 131 and the side surface of scintillator 131 are covered. Protective layer 133 is formed by a CVD method employing SiNx, for example.

S4: Step of Forming Transparent Electrode 100

Transparent electrode 100 is formed on protective layer 133 by a sputtering method, for example. Material of transparent electrode 100 is identical to that in the first embodiment.

Transparent electrode 100 preferably has a thickness t1 of 500 nm or less so as to transmit at least 70% of light emitted by scintilator 131. A thickness of at least 10 nm is necessary in order to acquire conductivity of transparent electrode 100. Accordingly, thickness t1 of transparent electrode 100 preferably satisfies 10 nm≦t1≦500 nm, but more preferably satisfies 10 nm≦t1≦200 nm.

Further, since light emitted by scintilator 131 is reflected at the interface between protective film 133 and transparent electrode 100, and at the interface between transparent electrode 100 and photoelectric conversion layer 101, reflectance with respect to central wavelength λ of light emitted by scintilator 131 at the interface is preferably minimized to be a minimum value. Reflectance R with respect to incoming light at the multilayered film, with respect to wavelength λ at the interface between protective film 133 and transparent electrode 100 can be determined from refractive index n2 and film thickness t2 of protective film 133, and refractive index n1 and film thickness t1 of transparent electrode 100 employing a commonly known theoretical formula. Since refractive index R has a minimum value and a maximum value with respect to wavelength λ because of the interference effect of light, the values of film thickness t1 and film thickness t2 are changed to determine the minimum value, and film thickness t1 and film thickness t2 practically formed in the range within 110% of the minimum value are arranged to be set.

In addition, after providing a planarization film on protective film 133, transparent electrode 100 may be formed. However, in this case, film thickness of each layer is desired to be optimized in such a way that reflectance R with respect to incoming light at the multilayered film including a planarization film is minimized to be the minimum value.

S5: Step of Forming Gate Electrode 2 and Source Line 8b

S6: Step of Forming Gate Insulation Layer 7

S7: Step of Forming Source Electrode 8a and Drain Electrode 9

S8: Step of Forming Active Layer 5

Since TFT 82 can be prepared with the same material and manufacturing method as in the first embodiment in the case of Steps up to S5-S8, explanation thereof is omitted.

S9: Step of Forming Passivation Layer 112

Passivation layer 112 is formed by spin-coating polyimide, for example.

S10: Step of Forming Photoelectric Conversion Layer 101

Similarly to the first embodiment, a solution in which an electron-accepting material and an electron-releasing material are dissolved in an organic solvent is coated onto the entire surface of supporting substrate 1 having been subjected to processes up to Step 9 by a spin-coating method, followed by drying to form bulk-heterojunction type photoelectric conversion layer 101.

In this way, bulk-heterojunction type photoelectric conversion layer 101 can be composed of only one layer as a photoelectric conversion layer, whereby the step can be simplified.

The electron-accepting organic material and the electron-releasing organic material are not limited thereto, and usable are various materials disclosed in Japanese Patent o.P.I. Publication No. 2005-32793, for example. Further, application to the present invention is not limited to the bulk-heterojunction type photoelectric conversion layer, and formed may be a stacking type photoelectric conversion layer in which layers formed of an electron-releasing organic material and layers formed of an electron-releasing organic material, disclosed in Japanese Patent o.P.I. Publication No. 2005-32793, for example, are laminated.

S11: Step of Forming Upper Electrode 102

Upper electrode 102 is formed on photoelectric conversion layer 101. Upper electrode 102 is formed via evaporation of a metal material such as Al, Ag, Au, Pt or the like, for example.

A photoelectric conversion element composed of transparent electrode 100, photoelectric conversion layer 101 and upper electrode 102 was able to be prepared via the foregoing steps.

S12: Step of Forming Protective Layer 103

Polyimide, for example, is coated onto the upper layer of upper electrode 102 by a spin-coating method.

This is the end of the manufacturing process of image sensor 20.

Since in such the way, light emitted by scintillator 131 enters photoelectric conversion layer 101 via protective film 133 and transparent electrode 100 without transmitting supporting substrate 1, clear images exhibiting excellent sensitivity can be image-taken with neither image-blurring of image-taken images, nor malfunction caused by scattering light entering TFT.

### EXAMPLE

Examples provided to confirm the effect of the present invention will be described, but the present invention is not limited thereto.

### Example 1

In Example 1, image sensor 20 of the first embodiment shown in FIG. 1e was prepared to confirm performance thereof.

Next, each step having been subjected to test production will be described in detail.

S1: Step of Forming Light Collector 51 in Supporting Substrate 1

Light collectors 51 of 100×100 pieces are formed on supporting substrate 1 measuring 50 mm by 60 mm. A PYREX (registered trademark) substrate having a thickness of 0.5 mm was employed as supporting substrate 1. Outgoing light surface 51a of light collector 51 has a diameter φ1 of 140 μm; incoming light surface 51b thereof has a diameter φ2 of 340 μl; and distance interval Px=distance interval Py=352.5 μm.

S1-1: Step of Forming Through-Hole 50

Through-holes 50 were formed employing a heat type nanoimprint technique.

S1-1-1: Heating Step

Die 200 and supporting substrate 1 are first heated to 650° C.

S1-1-2: Step of Pressing

Die pattern 201 of die 200 is pressed onto supporting substrate 1 at 5 Pa for 20 minutes while heating at 650° C. to transfer die pattern 201 onto supporting substrate 1.

S1-1-3: Step of Cooling/Releasing

Die 200 and supporting substrate 1 were cooled to temperature lower than glass transition temperature of supporting substrate 1 to release die 200 from supporting substrate 1.

S1-2: Step of Filling a Transparent Material in Through-Hole 50 of Supporting Substrate 1.

Polyimide was dropped in through-hole 50 by an ink-jet method, and was filled in through-hole 50.

S2: Step of Forming Scintillator 131

Scintillator 131 was formed by evaporating CsI on the incoming light surface 51b side of supporting substrate 1 in which light collector 51 was embedded.

S3: Step of Forming Protective Film 133

Protective film 133 was formed via a spin-coating method by using polyimide as a material.

S4: Step of Forming Transparent Electrode 100

An ITO film was formed as transparent electrode 100 on the outgoing light surface 51a side of supporting substrate 1 in which light collector 51 was embedded, employing a sputtering method. Film thickness t1 of transparent electrode 100 was set to 200 nm.

S5: Step of Forming Gate Electrode 2 and Source Line 8b

Ag dispersed in a solution was printed by a printing method to form gate electrode 2 and source line 8b.

S6: Step of Forming Gate Insulation Layer 7

Gate insulation layer 7 was formed, as shown in FIG. 1d.

Gate insulation layer 7 was formed via a spin-coating method by using polyimide as a material.

S7: Step of Forming Source Electrode 8a and Drain Electrode 9

Source electrode 8a and drain electrode 9 were formed via coating of a solution of PEDOT/PSS.

S8: Step of Forming Active Layer 5

Active layer 5 was formed via coating of a pentacene solution.

S9: Step of Forming Passivation Layer 112

Passivation layer 112 was formed via a spin-coating method by using polyimide as a material.

S10: Step of Forming Photoelectric Conversion Layer 101

A chlorobenzene solution having a weight ratio of PCBM (butyric acid methylester) as an electron-accepting organic material to P3HT (poly-3-hexylthiophene) as an electron-releasing organic material in 7:3 is coated via spin-coating, followed by heating with an oven at 100° C. for 30 minutes to form 70 nm thick photoelectric conversion layer 101.

S11: Step of Forming Upper Electrode 102

Upper electrode 102 was formed via evaporation of Au.

S12: Step of Forming Protective Layer 103

Protective layer 103 was formed via a spin-coating method by using polyamide as a material.

Radiation detector 22 was prepared employing image sensor 20 prepared in such the way.

[Experimental Result]

When radiation detector 22 prepared in Example 1 was exposed to X-ray to take images, clear images exhibiting excellent sensitivity were able to be image-taken with neither image-blurring of image-taken images, nor malfunction caused by scattering light entering TFT.

### Example 2

In Example 2, image sensor 20 of the second embodiment shown in FIG. 4c was prepared to confirm performance thereof.

S2: Step of Forming Scintillator 131

Scintillator 131 was formed on supporting substrate 1 composed of a transparent glass material measuring 50 mm by 60 mm via an evaporation method employing CsI as a material. Light emitted by Scintillator 131 has a wavelength λ of 550 nm. In addition, supporting substrate 1 has a thickness of 0.5 mm.

S3: Step of Forming Protective Film 133

SiNx was prepared via a CVD method to form protective film 133. The protective film has a film thickness of t2 of 520 nm.

S4: Step of Forming Transparent Electrode 100

Transparent electrode 100 was formed via a sputtering method by using ITO as a material. Transparent electrode 100 has a film thickness t1 of 200 nm. Reflectance R with respect to wavelength λ of light emitted by scintilator 131 at the interface between protective film 133 and transparent electrode 100 was 12% obtained via simulation.

S5: Step of Forming Gate Electrode 2 and Source Line 8b

S6: Step of Forming Gate Insulation Layer 7

S7: Step of Forming Source Electrode 8a and Drain Electrode 9

S8: Step of Forming Active Layer 5

Since an organic TFT has been prepared with the same material and manufacturing method as in the first embodiment in the case of Steps up to S5-S8, explanation thereof is omitted. Distance interval of the organic TFT is set to Px=distance interval Py=352.5 μm, and 100×100 pieces of the organic TFT are prepared on supporting substrate 1.

S9: Step of Forming Passivation Layer 112

Passivation layer 112 was formed by spin-coating polyimide as a material.

S10: Step of Forming Photoelectric Conversion Layer 101

A chlorobenzene solution having a weight ratio of PCBM (butyric acid methylester) as an electron-accepting organic material to P3HT (poly-3-hexylthiophene) as an electron-releasing organic material in 7:3 was coated via spin-coating, followed by heating with an oven at 100° C. for 30 minutes to form 70 nm thick photoelectric conversion layer 101.

S11: Step of Forming Upper Electrode 102

S12: Step of Forming Protective Film 103.

Since those have been prepared with the same material and manufacturing method as in the first embodiment in Steps of S11 and S12, explanation thereof is omitted.

[Experimental Result]

When radiation detector 22 prepared in Example 2 was exposed to X-ray to take images, clear images exhibiting excellent sensitivity were able to be image-taken with neither image-blurring of image-taken images, nor malfunction caused by scattering light entering TFT.

In addition, in the case of the photoelectric conversion element described in the present embodiment, photoelectric conversion layer 101 and upper electrode 102 are not separated to each other for each pixel, but they may be separated to each other for each pixel.

In such the way, in the present invention, provided can be a radiation detector containing an organic semiconductor material, by which clear images exhibiting excellent sensitivity can be taken, a method of manufacturing the radiation detector, and a method of manufacturing a supporting substrate.

1. A radiation detector comprising:
(a) a scintillator layer comprising a phosphor to convert radiation into visible light, formed on one surface of a supporting substrate;
(b) a transparent electrode formed on another surface of the supporting substrate;
(c) a photoelectric conversion layer comprising an organic semiconductor material, formed on the transparent electrode; and
(d) an upper electrode formed on the photoelectric conversion layer,
wherein light collectors to collect the visible light emitted by exposing the scintillator layer to radiation into the photoelectric conversion layer are embedded in the form of a matrix at a position facing the transparent electrode in the supporting substrate.

2. The radiation detector of claim 1, comprising the supporting substrate not transmitting the visible light.

3. The radiation detector of claim 1, comprising each of a plurality of the transparent electrodes formed in the form or a matrix, on the another surface of the supporting substrate.

4. A method of manufacturing a supporting substrate employed for a radiation detector of, the type including (a) a scintillator layer comprising a phosphor to convert radiation into visible light, formed on one surface of a supporting substrate, (b) a transparent electrode formed on another surface of the supporting substrate, (c) a photoelectric conversion layer comprising an organic semiconductor material, formed on the transparent electrode, and (d) an upper electrode formed on the photoelectric conversion layer, wherein light collectors to collect the visible light emitted by exposing the scintillator layer to radiation into the photoelectric conversion layer are embedded in the form of a matrix at a position facing the transparent electrode in the supporting substrate, the method of manufacturing the supporting substrate comprising the steps of:
(a) forming a plurality of through-holes in the form of a matrix so as to pass through from one surface of the supporting substrate to another surface of the supporting substrate, and
(b) filling a transparent material in the through-holes.

5. The method of claim 4,
wherein the step of forming a plurality of through-holes in the form of a matrix is a step of forming the through-holes employing a nanoimprint technique.

6. A method of manufacturing a radiation detector, comprising the steps of:
(a) forming a scintillator layer comprising a phosphor to convert radiation into visible light, on one surface of the supporting substrate manufactured by the method of claim 4;
(b) forming a transparent electrode on another surface of the supporting substrate;
(c) forming a photoelectric conversion layer comprising an organic semiconductor material, on the transparent electrode; and
(d) forming an upper electrode on the photoelectric conversion layer,
wherein the photoelectric conversion layer is formed with a solution in which an electron-accepting organic material and an electron-releasing organic material are dissolved in an organic solvent.

7. A radiation detector comprising:
(a) a scintillator layer comprising a phosphor to convert radiation into visible light, formed on one surface of a supporting substrate;
(b) a protective film formed on the scintillator layer;
(c) a transparent electrode formed on the protective film;
(d) a photoelectric conversion layer comprising an organic semiconductor material, formed on the transparent electrode; and
(e) an upper electrode formed on the photoelectric conversion layer.

8. The radiation detector of claim 7,
wherein the transparent electrode has a thickness T1 of at least 10 nm and not more than 500 nm.

9. The radiation detector of claim 7,
wherein an overall reflectance produced at an interface between the scintillator layer and the photoelectric conversion layer is within 110% of a theoretical minimum value of the reflectance with respect to a central wavelength of light emitted by the scintillator layer.

10. The radiation detector of claim 7, comprising a plurality of the transparent electrodes formed in the form of a matrix on the protective film.

11. A method of manufacturing a radiation detector of the type including (a) a scintillator layer comprising a phosphor to convert radiation into visible light, formed on one surface of a supporting substrate, (b) a protective film formed on the scintillator layer, (c) a transparent electrode formed on the protective film, (d) a photoelectric conversion layer comprising an organic semiconductor material, formed on the transparent electrode, and (e) an upper electrode formed on the photoelectric conversion layer, the method of manufacturing the radiation detector comprising the step of:
forming the photoelectric conversion layer, employing a solution in which an electron-accepting organic material and an electron-releasing organic material are dissolved.
